(19) United States
(12) Patent Application Publication
(10) Pub. No.: US 2017/0008759 A1
(43) Pub. Date: Jan. 12, 2017

(54) MICROPHONE AND CONTROL METHOD THEREFOR

(71) Applicant: HYUNDAI MOTOR COMPANY, Seoul (KR)

(72) Inventor: Ilseon YOO, Seoul (KR)

(21) Appl. No.: 14/945,627

(22) Filed: Nov. 19, 2015

(30) Foreign Application Priority Data
Jul. 7, 2015 (KR) 10-2015-0096815

(51) Int. Cl. B81B 3/00; H04R 19/04; H04R 3/00

(52) U.S. Cl. CPC B81B 3/0086; H04R 3/007; H04R 19/04; B81B 3/0021; H04R 2201/003

(57) ABSTRACT

A microphone includes a case including a sound hole; a sound element which outputs a sound output signal based on a sound signal that enters the case through the sound hole; and a semiconductor chip connected to the sound element and configured to adjust an applied voltage which is applied to the sound element in accordance with the sound output signal. A rigidity of a vibration layer of the sound element is adjusted in accordance with the applied voltage.

### CROSS-REFERENCE TO RELATED APPLICATION

This application claims the benefit of priority to Korean Patent Application No. 10-2015-0096815, filed in the Korean Intellectual Property Office on Jul. 7, 2015, the entire content of which is incorporated herein by reference.

### TECHNICAL FIELD

The present disclosure relates to a microphone and a control method thereof, and more particularly, to a microphone which may increase sensitivity without adding a separate circuit and a control method thereof.

### BACKGROUND

A microphone is a device which converts sound into an electrical signal. The microphone may be applied to mobile communication equipment such as a telephone and various communication equipment such as an earphone or a hearing aid.

A capacitive microphone based on a micro electromechanical system (MEMS) (hereinafter, simply referred to as a “MEMS microphone”) has excellent sound performance, reliability, and operability as compared with an electret condenser microphone (hereinafter, simply referred to as an “ECM” microphone) of the related art.

The MEMS microphone may be classified into a piezoelectric MEMS microphone and a capacitive MEMS microphone.

The piezoelectric MEMS microphone contains a a vibration layer and measures a sound pressure by an electric signal generated by the piezoelectric effect when the vibration layer responds to an external sound pressure.

The capacitive MEMS microphone contains a fixed electrode and a vibration layer and when a sound signal is applied from the outside to the vibration layer, the interval between the fixed electrode and the vibration layer is changed so that the capacitance varies. The sound pressure is measured by an electric signal generated in this case.

However, in the capacitive MEMS microphone of the related art as described above, the vibration displacement of the vibration layer is restricted, and so the level of sensitivity by the above-mentioned method is also limited.

In order to overcome this problem, a method which simultaneously outputs a different type of signal and adds this signal to increase the sensitivity may be introduced.

However, according to the methods of the related art, a signal processing circuit for each of the two output signals is required and an additional circuit for adding the two output signals is also required.

Therefore, the semiconductor chip area is increased, which increases the cost as well as the power consumption.

The above information disclosed in this Background section is only for enhancement of understanding of the background of the disclosure and therefore it may contain information that does not form the prior art that is already known in this country to a person of ordinary skill in the art.

### SUMMARY

The present disclosure has been made in an effort to provide a microphone which has a wide dynamic range so as to actively cope with a variable environment such as the inside of a vehicle and a control method thereof.

One or a plurality of exemplary embodiments in the disclosure provides a microphone including: a case including a sound hole at one side; a sound element which outputs a sound output signal using a sound signal which flows into the sound hole in the case; and a semiconductor chip which is connected to the sound element and adjusts an applied voltage which is applied to the sound element in accordance with the sound output signal in which a rigidity of a vibration layer of the sound element changes in accordance with the applied voltage.

The semiconductor chip may measure an output sound pressure of a sound output signal which is input from the sound element and compare the output sound pressure and a predetermined set sound pressure to adjust the applied voltage.

The semiconductor chip may lower the applied voltage which is applied to the sound element when the output sound pressure is equal to or higher than a set sound pressure.

Further, the sound element may include a substrate, a vibration layer located on the substrate; and a fixed layer which is located to be spaced apart from the vibration layer at a predetermined interval.

Further, the semiconductor chip may apply an applied voltage between the vibration layer and the fixed layer.

A level of the applied voltage may be inversely proportional to the rigidity of the vibration layer.

Further, a level of the applied voltage may be proportional to a level of the output sound pressure of the sound output signal.

The sound element may be formed to be a capacitive type or a piezo electric type.

One or a plurality of exemplary embodiments in the disclosure provides a control method of a microphone, including: outputting, by a sound element, a sound output signal to a semiconductor chip using a sound signal which flows from the outside; measuring, by the semiconductor chip, an output sound pressure based on the sound output signal; comparing, by the semiconductor chip, a level of the output sound pressure and a level of a predetermined set sound pressure; and adjusting, by the semiconductor chip, an applied voltage which is applied to the sound element in accordance with the output sound pressure.

The adjusting, by the semiconductor chip, an applied voltage may include lowering the applied voltage when the output sound pressure has a level equal to or higher than that of the set sound pressure.

Further, in the adjusting, by the semiconductor chip, an applied voltage, when the output sound pressure is higher than the set sound pressure, the applied voltage may be lowered until the level of the output sound pressure is lower than the level of the set sound pressure.

Further, the level of the applied voltage may be inversely proportional to a rigidity of the vibration layer and may be proportional to a level of the output sound pressure of the sound output signal.

Further, the control method may further include, after the adjusting, by the semiconductor chip, an applied voltage, outputting, by the semiconductor chip, a final signal when the output sound pressure has a level lower than that of the set sound pressure.

According to an exemplary embodiment in the disclosure, the rigidity of the vibration layer of the sound element is changed depending on an applied voltage which is applied by the semiconductor chip to implement a wide dynamic range so as to actively adjust the variable environment such as inside the vehicle.

Further, the variable sound signal in the vehicle is determined based on a predetermined value which is set in the semiconductor chip in advance and when the sound signal which is equal to or higher than a predetermined value is generated, the semiconductor chip adjusts an applied voltage to prevent the sound element from being damaged due to an abnormal signal and excessive sound pressure.

Other effects which may be achieved or expected by the exemplary embodiment in the disclosure may be directly or implicitly disclosed in the detailed description of the exemplary embodiment in the disclosure. Various effects which are expected by the exemplary embodiment in the disclosure will be disclosed in the following detailed description.

### BRIEF DESCRIPTION OF THE DRAWINGS

FIG. 1 is a schematic diagram illustrating a microphone according to an exemplary embodiment in the disclosure.

FIG. 2 is a flowchart illustrating a control method of a microphone according to an exemplary embodiment in the disclosure.

FIGS. 3A and 3B are graphs illustrating a sensitivity and a maximum input sound pressure which vary depending on an applied voltage which is applied to a sound element by a semiconductor chip of a microphone according to an exemplary embodiment in the disclosure.

### DETAILED DESCRIPTION OF THE EMBODIMENTS

Hereinafter, an exemplary embodiment in the disclosure will be described with reference to the accompanying drawings. However, the drawings illustrated below and the following detailed description are about exemplary embodiments among several exemplary embodiments which effectively describe a feature of the present inventive concept. Therefore, the present inventive concept is not limited only to the following drawings and the following description.

In the following description of the inventive concept, a detailed description of known functions or configurations incorporated herein will be omitted when it is determined that the detailed description may unnecessarily make the subject matter of the disclosure unclear. Further, the terms used in the description are defined considering the functions of the present inventive concept and may vary depending on the intention or usual practice of a user or operator. Accordingly, the terms need to be defined based on details throughout the present inventive concept.

Further, in the following exemplary embodiment, in order to efficiently describe a core technical feature of the present inventive concept, terms may be appropriately changed, combined, or separated so as to be clearly understood by those skilled in the art, but the present inventive concept is never limited thereto.

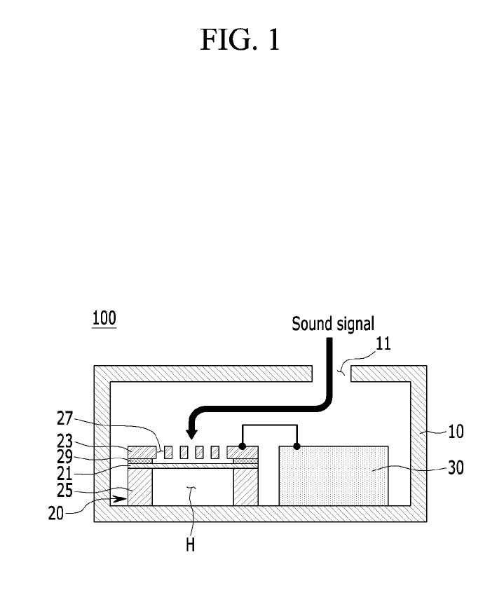

FIG. 1 is a schematic diagram schematically illustrating a microphone according to an exemplary embodiment in the disclosure.

Referring to FIG. 1, a microphone 100 according to an exemplary embodiment in the disclosure includes a case 10, a sound element 20, and a semiconductor chip 30.

First, the case 10 is formed to include a sound hole 11 in an upper portion and a predetermined receiving space therein.

Here, the sound hole 11 is a passage into which a voice signal generated from an external voice processing device (not illustrated) flows.

Further, the voice processing device processes voice of a user and may be at least one of a voice recognizing device, a hands free device, and a portable communication terminal.

Further, the voice recognizing device performs a function of recognizing a command which is issued by a voice of the user to perform the command issued by the user.

Further, the hands free device is connected to the portable communication terminal through a near field wireless communication so that the user may freely make a call without holding the portable communication terminal by hands.

Further, the portable communication terminal is a device which may wirelessly make a call and may be a smart phone or personal digital assistants (PDA).

The sound element 20 is located in the case 10 and receives the sound signal which flows into the sound hole 11.

In other words, the sound element 20 detects the sound signal which is generated from the voice processing device through the vibration layer 21 and the fixed layer 23 to output a sound output signal to the semiconductor chip 30.

Such a sound element 20 may be a capacitive micro electromechanical system (MEMS) element based on an MEMS technique.

The semiconductor chip 30 is electrically connected to the sound element 20 in the case 10. As long as the semiconductor chip 30 is electrically connected to the sound element 20, the position of the semiconductor chip 30 may be flexible. For example, the semiconductor chip 30 may be electrically connected to the sound element 20 outside the case 10.

The semiconductor chip 30 varies a voltage which is applied to the vibration layer 21 of the sound element 20 in accordance with a sound output signal which is output from the sound element 20.

In more detail, the semiconductor chip 30 receives the sound output signal generated from the sound element 20 to measure a level of the output sound pressure and compares and measures the level of the output sound pressure and a level of a predetermined set sound pressure.

Next, when the level of the output sound pressure is higher than the level of the set sound pressure, the semiconductor chip 30 applies the applied voltage to the sound element 20.

In this case, the semiconductor chip 30 applies the applied voltage between the vibration layer 21 and the fixed layer 23 in the sound element 20 and changes a rigidity of the vibration layer 21 by the applied voltage.

When the rigidity of the vibration layer 21 is lowered, the sensitivity is increased and the maximum input sound pressure is lowered.

That is, the semiconductor chip 30 increases the applied voltage in the low sound output signal to lower the rigidity of the vibration layer 21 and resultantly increase the sensitivity.

In contrast, the semiconductor chip 30 lowers the applied voltage in the high sound output signal to increase the rigidity of the vibration layer 21 and resultantly increase the maximum input sound pressure.

In this case, the semiconductor chip 30 lowers the applied voltage which is applied to the sound element 20 until the level of the output sound pressure is lower than the level of the set sound pressure.

In this way, the output sound pressure of the sound output signal may be lowered through the applied voltage to improve a dynamic range which is one factor affecting the performance of the sound element 20.

Here, the dynamic range is the difference between the maximum signal level which may be processed by the sound element 20 and the noise level of the sound element 20 and it means how strong a signal may be processed by the sound element 20 without damaging the sound element 20.

Here, the applied voltage is inversely proportional to the rigidity of the vibration layer 21 and proportional to the level of the output sound pressure of the sound output signal.

Further, the set sound pressure may indicate a level of sound which allows the user to smoothly make a call or recognize a voice.

The set sound pressure may be set by the user or set through a predetermined algorithm, for example, a program or a probability model.

Further, the set sound pressure is not a fixed value, but may be changed depending on circumstances.

To this end, the semiconductor chip 30 may be implemented as at least one processor which operates by a predetermined program and the predetermined program may be programmed to execute individual steps of the control method of the microphone according to the exemplary embodiment in the disclosure.

The semiconductor chip 30 described above may be implemented using at least one of application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, and other electric units for performing functions.

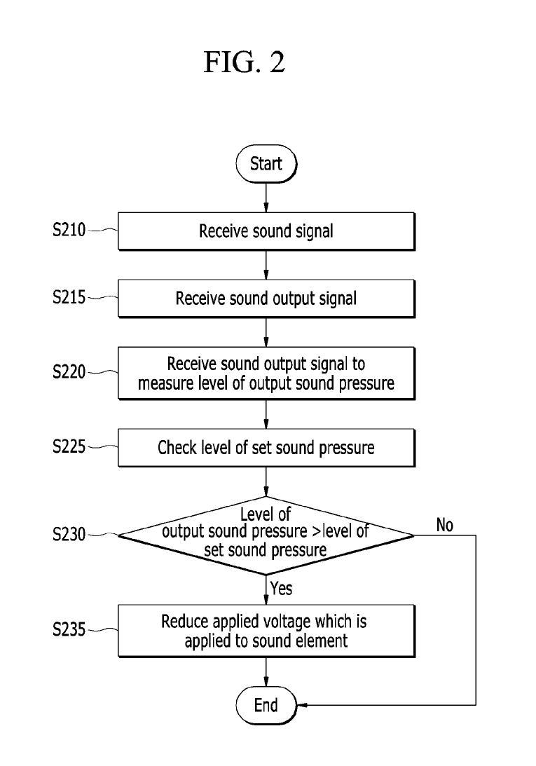

Hereinafter, a control method of a microphone according to an exemplary embodiment in the disclosure will be described with reference to FIG. 2.

FIG. 2 is a flowchart illustrating a control method of a microphone according to an exemplary embodiment in the disclosure.

Referring to FIG. 2, a semiconductor chip 30 receives a sound signal through a sound element 20 in step S210.

When a sound signal enters the sound element 20 from the outside, a vibration layer 21 vibrates to generate a sound output signal and the sound element 20 transmits the sound output signal to the semiconductor chip 30.

The semiconductor chip 30 receives the sound signal from the sound element 20 in step S215.

Next, the semiconductor chip 30 measures the sound output signal which is received from the sound element 20 to check an output sound pressure in step S220.

Furthermore, the semiconductor chip 30 checks a level of a predetermined set sound pressure in advance in step S225.

In this case, the set sound pressure may have a predetermined level to prevent damage to the sound element 20 and minimize a noise generated in the sound signal.

Next, the semiconductor chip 30 determines whether the level of the output sound pressure received from the sound element 20 is equal to or higher than a level of the set sound pressure in step S230.

When the level of the output sound pressure is equal to or larger than a level of the set sound pressure, the semiconductor chip 30 lowers an applied voltage which is applied to the sound element 20 in step S235.

The semiconductor chip 30 lowers the applied voltage applied to the sound element 20 until the level of the output sound pressure is lower than the level of the set sound pressure.

When the level of the output sound pressure is lower than the level of the set sound pressure, the semiconductor chip 30 outputs a final signal.

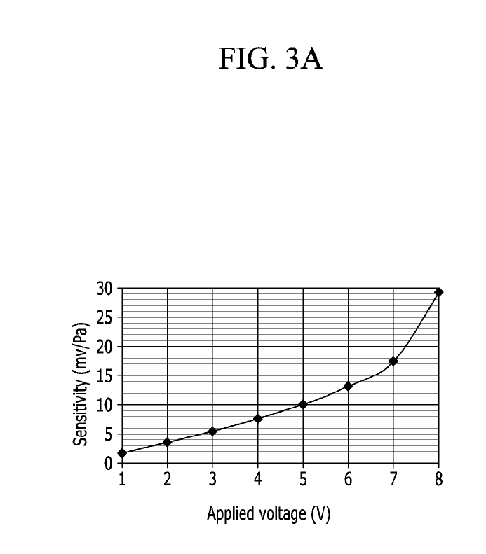

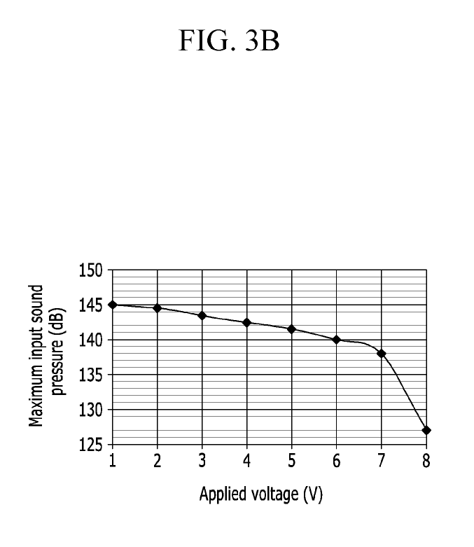

FIGS. 3A and 3B are graphs illustrating a sensitivity and a maximum input sound pressure which vary depending on an applied voltage which is applied to the sound element 20 by the semiconductor chip 30.

As illustrated in FIG. 3A, in a microphone 100 according to an exemplary embodiment in the disclosure, a rigidity of a vibration layer 21 is decreased as the applied voltage is increased, so that the sensitivity is increased but a frequency response range is reduced.

Further, as illustrated in FIG. 3B, it can be seen that as the applied voltage is increased, the rigidity of the vibration layer 21 is decreased, so that the maximum input sound pressure is lowered.

Thus, the sensitivity is increased and the maximum input sound pressure is lowered as the applied voltage is increased.

Therefore, in the microphone 100 according to the exemplary embodiment in the disclosure, a semiconductor chip 30 which actively reacts in accordance with the input sound signal is applied to improve the sensitivity.

In other words, in the microphone 100 according to the exemplary embodiment in the disclosure, the rigidity of the vibration layer 21 changes depending on the applied voltage to increase a sensitivity by increasing the applied voltage in the low-volume sound signal and increase the maximum input sound pressure by lowering the applied voltage in response to a high-volume sound signal, thereby actively coping with a variable input sound pressure environment to achieve a wide dynamic range.

Further, the microphone 100 according to the exemplary embodiment in the disclosure may determine a sound signal which is generated under a variable environment with respect to a set sound pressure which is set in the semiconductor chip 30 in advance. When a signal which is equal to or larger than the set sound pressure is generated, the semiconductor chip 30 adjusts the applied voltage to prevent the sound element 20 from being damaged due to an abnormal signal and an excessive sound pressure.

While this inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

What is claimed is:

1. A microphone, comprising:
a case including a sound hole;
a sound element which outputs a sound output signal based on a sound signal that enters the case through the sound hole; and
a semiconductor chip connected to the sound element and configured to adjust an applied voltage which is applied to the sound element in accordance with the sound output signal;
wherein a rigidity of a vibration layer of the sound element is adjusted in accordance with the applied voltage.

2. The microphone of claim 1, wherein:
the semiconductor chip measures an output sound pressure of the sound output signal and compares the output sound pressure and a predetermined set sound pressure to adjust the applied voltage.

3. The microphone of claim 2, wherein:
the semiconductor chip lowers the applied voltage when the output sound pressure is equal to or higher than the set sound pressure.

4. The microphone of claim 1, wherein:
the sound element includes:
a substrate;
a vibration layer disposed on the substrate; and
a fixed layer which is disposed to be spaced apart from the vibration layer by a predetermined interval.

5. The microphone of claim 4, wherein:
the semiconductor chip applies the applied voltage between the vibration layer and the fixed layer.

6. The microphone of claim 5, wherein:
the applied voltage is inversely proportional to the rigidity of the vibration layer.

7. The microphone of claim 5, wherein:
the applied voltage is proportional to the output sound pressure of the sound output signal.

8. The microphone of claim 1, wherein:
the sound element is a capacitive type sound element or a piezoelectric type sound element.

9. A control method of a microphone, comprising steps of:
outputting, by a sound element, a sound output signal to a semiconductor chip based on a sound signal from the outside;
measuring, by the semiconductor chip, an output sound pressure based on the sound output signal;
comparing, by the semiconductor chip, the output sound pressure to a predetermined set sound pressure; and
adjusting, by the semiconductor chip, an applied voltage which is applied to the sound element in accordance with the output sound pressure.

10. The control method of claim 9, wherein:
the step of adjusting the applied voltage includes lowering the applied voltage when the output sound pressure is equal to or higher than the set sound pressure.

11. The control method of claim 10, wherein:
in the step of adjusting the applied voltage, the applied voltage is lowered until the output sound pressure is lower than the set sound pressure when the output sound pressure is higher than the set sound pressure.

12. The control method of claim 9, wherein:
the applied voltage is inversely proportional to a rigidity of the vibration layer and is proportional to the output sound pressure of the sound output signal.

13. The control method of claim 9, further comprising:
outputting, by the semiconductor chip, a final signal when the output sound pressure is lower than the set sound pressure after the step of adjusting the applied voltage.
